(19) United States
(12) Patent Application Publication
(10) Pub. No.: US 2025/0393207 A1
(43) Pub. Date: Dec. 25, 2025

(54) SEMICONDUCTOR DEVICE AND METHOD OF MANUFACTURING THE SAME

(71) Applicant: Kioxia Corporation, Tokyo (JP)

(72) Inventor: Shun SHIMIZU, Yokkaichi Mie (JP)

(73) Assignee: Kioxia Corporation, Tokyo (JP)

(21) Appl. No.: 18/960,174

(22) Filed: Nov. 26, 2024

(30) Foreign Application Priority Data
Jun. 25, 2024 (JP) 2024-102425

(51) Int. Cl. H10B 43/27

(52) U.S. Cl. CPC H10B 43/27

(57) ABSTRACT

In one embodiment, a semiconductor device includes a stacked film alternately including electrode layers and first insulators in a first direction, and a plate-like portion provided in the stacked film, having a plate-like shape that extends in the first direction and a second direction, and provided between a first portion and a second portion of the stacked film. The device further includes a first columnar portion provided in the first portion, and a second columnar portion provided in the second portion. A first electrode layer among the electrode layers includes a first region where concentration of boron, carbon or nitrogen has a first value, and a second region where concentration of boron, carbon or nitrogen has a second value higher than the first value, and the second region is provided in a vicinity of a side face of the first electrode layer, the side face facing the plate-like portion.

### CROSS REFERENCE TO RELATED APPLICATION

This application is based upon and claims the benefit of priority from the prior Japanese Patent Application No. 2024-102425, filed on Jun. 25, 2024, the entire contents of which are incorporated herein by reference.

### FIELD

Embodiments described herein relate to a semiconductor device and a method of manufacturing the same.

### BACKGROUND

When electrode layers of a three-dimensional semiconductor memory (e.g., word lines) are formed by replacement processing, a slit is formed in a stacked film including sacrifice layers, the sacrifice layers are removed from the slit to form concave portions in the stacked film, and the electrode layers are formed in the concave portions. In this case, undesirable impurity atoms potentially diffuse into the electrode layers from the slit after the electrode layers are formed.

### BRIEF DESCRIPTION OF THE DRAWINGS

FIG. 1 is a perspective view illustrating a structure of a semiconductor device of a first embodiment;

FIG. 2 is a cross-sectional view illustrating the structure of the semiconductor device of the first embodiment;

FIGS. 3 to 10 are cross-sectional views illustrating a method of manufacturing the semiconductor device of the first embodiment;

FIG. 11 is a cross-sectional view illustrating a method of manufacturing a semiconductor device of a comparative example of the first embodiment;

FIGS. 12 and 13 are cross-sectional views illustrating a first example of the method of manufacturing the semiconductor device of the first embodiment;

FIGS. 14 and 15 are cross-sectional views illustrating a second example of the method of manufacturing the semiconductor device of the first embodiment;

FIGS. 16 and 17 are cross-sectional views illustrating a third example of the method of manufacturing the semiconductor device of the first embodiment;

FIGS. 18 and 19 are cross-sectional views illustrating a fourth example of the method of manufacturing the semiconductor device of the first embodiment;

FIG. 20 is an enlarged cross-sectional view illustrating the structure of the semiconductor device of the first embodiment;

FIG. 21 is a cross-sectional view illustrating a structure of a semiconductor device of a second embodiment; and

FIG. 22 is an enlarged cross-sectional view illustrating the structure of the semiconductor device of the second embodiment.

### DETAILED DESCRIPTION

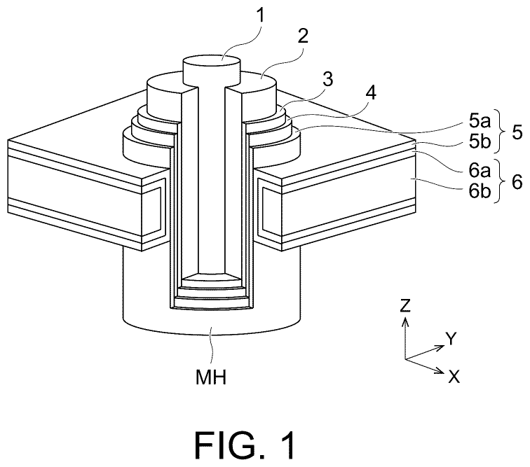

Embodiments will now be explained with reference to the accompanying drawings. In FIGS. 1 to 22, identical components are denoted by the same reference sign, and duplicate description thereof is omitted.

In one embodiment, a semiconductor device includes a stacked film alternately including a plurality of electrode layers and a plurality of first insulators in a first direction, and a plate-like portion provided in the stacked film, having a plate-like shape that extends in the first direction and a second direction intersecting the first direction, and provided between a first portion and a second portion of the stacked film. The device further includes a first columnar portion provided in the first portion, extending in the first direction, and including a first charge storing layer and a first semiconductor layer, and a second columnar portion provided in the second portion, extending in the first direction, and including a second charge storing layer and a second semiconductor layer. A first electrode layer among the electrode layers includes a first region where concentration of boron, carbon or nitrogen has a first value, and a second region where concentration of boron, carbon or nitrogen has a second value higher than the first value, and the second region is provided in a vicinity of a side face of the first electrode layer, the side face of the first electrode layer facing the plate-like portion.

### First Embodiment

FIG. 1 is a perspective view illustrating a structure of a semiconductor device of a first embodiment. The semiconductor device of the present embodiment is, for example, a three-dimensional semiconductor memory.

In FIG. 1, the semiconductor device of the present embodiment includes a core insulator 1, a channel semiconductor layer 2, a tunnel insulator 3, a charge storing layer 4, a block insulator 5, and an electrode layer 6. The block insulator 5 includes an insulator 5a and an insulator 5b. The electrode layer 6 includes a barrier metal layer 6a and an electrode material layer 6b.

In FIG. 1, a plurality of electrode layers and a plurality of insulators are alternately stacked on a substrate, and a memory hole MH is provided in these electrode layers and insulators. FIG. 1 illustrates the electrode layer 6 as one of the electrode layers. The electrode layers function as, for example, word lines or select lines of the three-dimensional semiconductor memory. FIG. 1 illustrates an X direction and a Y direction parallel to the surface of the substrate and orthogonal to each other, and a Z direction orthogonal to the surface of the substrate. The X direction, the Y direction, and the Z direction intersect each other. In the present specification, the positive Z direction is defined as the upward direction, and the negative Z direction is defined as the downward direction. The negative Z direction may or may not align with the direction of gravity. The Z direction is an example of a first direction, and the Y direction is an example of a second direction.

The core insulator 1, the channel semiconductor layer 2, the tunnel insulator 3, the charge storing layer 4, and the insulator 5a are sequentially formed in the memory hole MH and constitute a plurality of memory cells of the three-dimensional semiconductor memory. The insulator 5a is formed on the side faces of the electrode layers and the insulators in the memory hole MH, and the charge storing layer 4 is formed on the side face of the insulator 5a. The charge storing layer 4 can store signal electric charges in the three-dimensional semiconductor memory. The tunnel insulator 3 is formed on the side face of the charge storing layer 4, and the channel semiconductor layer 2 is formed on the side face of the tunnel insulator 3. The channel semiconductor layer 2 functions as a channel in the three-dimensional semiconductor memory. The core insulator 1 is formed on the side face of the channel semiconductor layer 2.

The insulator 5a is, for example, a silicon oxide film (SiO₂ film). The charge storing layer 4 is, for example, a silicon nitride film (SiN film). The tunnel insulator 3 is, for example, a SiO₂ film. The channel semiconductor layer 2 is, for example, a polysilicon layer. The core insulator 1 is, for example, a SiO₂ film.

The memory hole MH has a columnar shape extending in the Z direction and has a circular shape in a plan view. Accordingly, the core insulator 1, the channel semiconductor layer 2, the tunnel insulator 3, the charge storing layer 4, and the insulator 5a in the memory hole MH form a columnar portion having a columnar shape extending in the Z direction.

The insulator 5b, the barrier metal layer 6a, and the electrode material layer 6b are formed between two of the above-described insulators and sequentially formed on the lower face of the upper insulator, the upper face of the lower insulator, and the side face of the insulator 5a. The insulator 5b is, for example, an aluminum oxide film (Al₂O₃ film). The barrier metal layer 6a is, for example, a titanium nitride film (TiN film). The electrode material layer 6b is, for example, a tungsten (W) layer.

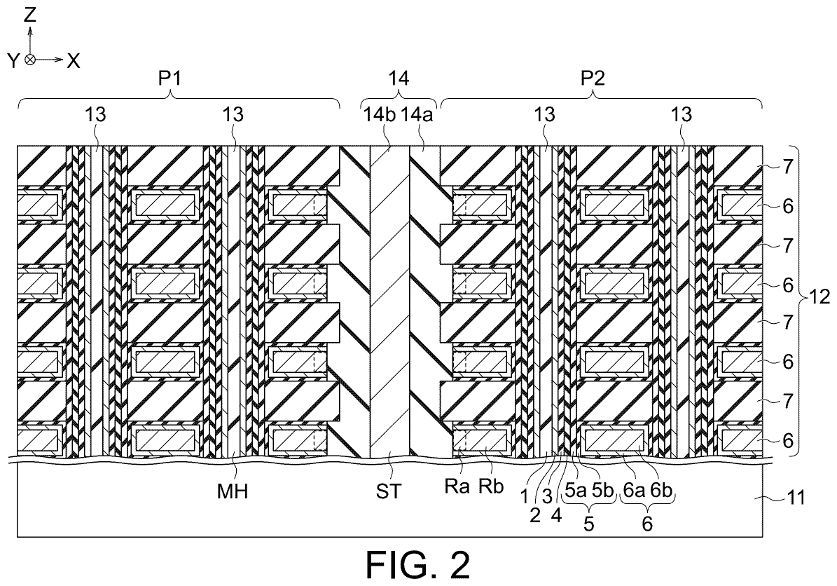

FIG. 2 is a cross-sectional view illustrating the structure of the semiconductor device of the first embodiment.

In FIG. 2, the semiconductor device of the present embodiment includes a substrate 11, a stacked film 12, a plurality of columnar portions 13, and a plate-like portion 14.

The substrate 11 corresponds to “the substrate” mentioned in the description of FIG. 1. The substrate 11 is, for example, a semiconductor substrate such as a silicon (Si) substrate. In a case where the substrate 11 and another substrate are bonded together to manufacture the semiconductor device of the present embodiment, the substrate 11 may be removed before the semiconductor device of the present embodiment is completed. In this case, the semiconductor device of the present embodiment may not include the substrate 11.

The stacked film 12 is formed above the substrate 11 and alternately includes a plurality of electrode layers 6 and a plurality of insulators 7 in the Z direction. The electrode layers 6 and the insulators 7 correspond to “the electrode layers and the insulators” mentioned in the description of FIG. 1. Accordingly, similarly to the electrode layer 6 illustrated in FIG. 1, each electrode layer 6 illustrated in FIG. 2 includes the barrier metal layer 6a and the electrode material layer 6b. Each electrode layer 6 illustrated in FIG. 2 is an example of a first electrode layer. Each insulator 7 is, for example, a SiO₂ film. Each insulator 7 is an example of a first insulator. The stacked film 12 also include a plurality of insulators 5b. The upper face, lower face, and side face of each electrode material layer 6b are sequentially covered by the corresponding barrier metal layer 6a and insulator 5b.

The stacked film 12 illustrated in FIG. 2 includes portions P1 and P2 adjacent to each other in the X direction. The portion P1 is an example of a first portion, and the portion P2 is an example of a second portion. Further details of the portions P1 and P2 will be described later.

Each columnar portion 13 includes the insulator 5a, the charge storing layer 4, the tunnel insulator 3, the channel semiconductor layer 2, and the core insulator 1, which are sequentially formed in the stacked film 12. In FIG. 2, the insulator 5a, the charge storing layer 4, the tunnel insulator 3, the channel semiconductor layer 2, and the core insulator 1 are sequentially formed on the side face of the stacked film 12. Each columnar portion 13 is formed in the memory hole MH formed in the stacked film 12. Each columnar portion 13 has a columnar shape extending in the Z direction and has a circular shape in a plan view. Each columnar portion 13 of the present embodiment is formed to penetrate through the stacked film 12 in the Z direction.

The semiconductor device of the present embodiment includes a plurality of columnar portions 13 provided in the portion P1 and a plurality of columnar portions 13 provided in the portion P2. The former columnar portions 13 are an example of first columnar portions, and the latter columnar portions 13 are an example of second columnar portions. The charge storing layer 4 and the channel semiconductor layer 2 in each former columnar portion 13 are examples of a first charge storing layer and a first semiconductor layer, and the charge storing layer 4 and the channel semiconductor layer 2 in each latter columnar portion 13 are examples of a second charge storing layer and a second semiconductor layer. In FIG. 2, the columnar portions 13 are disposed in the stacked film 12 so as not to contact each other. One of the columnar portions 13 corresponds to “the columnar portion” mentioned in the description of FIG. 1.

The plate-like portion 14 includes an insulator 14a and an interconnect layer 14b sequentially formed in the stacked film 12. In FIG. 2, the insulator 14a is formed on the side face of the stacked film 12, and the interconnect layer 14b is formed on the side face of the insulator 14a. The insulator 14a is, for example, a SiO₂ film. The insulator 14a is an example of a second insulator. The interconnect layer 14b is, for example, a polysilicon layer or a metal layer. The interconnect layer 14b of the present embodiment is electrically insulated from the electrode layers 6. The plate-like portion 14 is formed in a slit ST formed in the stacked film 12. The plate-like portion 14 has a plate-like shape extending in the Z and Y directions and has a straight shape in a plan view. This is the same for the slit ST. The slit ST may be completely filled with the insulator 14a in place of the interconnect layer 14b. Alternatively, an insulator different from the insulator 14a may be used in place of the interconnect layer 14b. In this case, the insulator different from the insulator 14a may be an insulator having a composition different from that of the insulator 14a and may be, for example, an oxide insulator or a nitride insulator.

The plate-like portion 14 is provided between the portions P1 and P2. The portions P1 and P2 of the present embodiment are divided from each other by the plate-like portion 14. In the present embodiment, the slit ST is formed to divide the stacked film 12 into the portions P1 and P2, and the plate-like portion 14 is formed in the slit ST. The semiconductor device of the present embodiment includes a plurality of plate-like portions in the stacked film 12, and FIG. 2 illustrates the plate-like portion 14 as one of the plate-like portions. The plate-like portion 14 may include the insulator 14a and the interconnect layer 14b or may include only the insulator 14a.

Further details of the electrode layers 6 will be described below.

As described above, each electrode layer 6 includes the barrier metal layer 6a and the electrode material layer 6b. The electrode material layer 6b is, for example, a metal layer including a predetermined metal element. The metal element is, for example, a transition metal element such as a Group 4 element, a Group 5 element, or a Group 6 element. Examples of the metal element include titanium (Ti), zirconium (Zr), hafnium (Hf), vanadium (V), niobium (Nb), tantalum (Ta), chromium (Cr), molybdenum (Mo), and tungsten (W). The electrode material layer 6b of the present embodiment is, for example, a W layer including W element as the above-described predetermined metal element. The barrier metal layer 6a of the present embodiment is, for example, a TiN film. Each electrode layer 6 may include only the electrode material layer 6b instead of including the barrier metal layer 6a and the electrode material layer 6b.

The electrode material layer 6b of the present embodiment also includes boron (B), carbon (C), or nitrogen (N). In the following description, the electrode material layer 6b includes W element and B element. In the present embodiment, the atomic concentration (B concentration) of B element in the electrode material layer 6b is different among regions in the electrode material layer 6b as described later. “B element” mentioned in the description below may be replaced with C element or N element.

In the present embodiment, the electrode material layer 6b in each electrode layer 6 includes a region Ra and a region Rb. In FIG. 2, the side face of the electrode material layer 6b in the positive X direction in the portion P1 and the side face of the electrode material layer 6b in the negative X direction in the portion P2 face the plate-like portion 14 (slit ST). The region Ra is provided in the vicinity of these side faces in the electrode material layer 6b, and the region Rb is provided apart from these side faces in the electrode material layer 6b. In other words, the region Ra is positioned near the plate-like portion 14, and the region Rb is positioned far from the plate-like portion 14. The region Rb is an example of a first region, and the region Ra is an example of a second region.

As described above, the semiconductor device of the present embodiment includes a plurality of plate-like portions in the stacked film 12. The portion P1 is provided between the plate-like portion 14 (hereinafter referred to as a “first plate-like portion”) illustrated in FIG. 2 and another plate-like portion (hereinafter referred to as a “second plate-like portion”). The region Ra in the portion P1 is positioned near the first plate-like portion or the second plate-like portion, and the region Rb in the portion P1 is positioned far from the first plate-like portion and the second plate-like portion. This is the same for the regions Ra and Rb in the portion P2. Details of the regions Ra and Rb will be described below using the regions Ra and Rb illustrated in FIG. 2 as examples.

The regions Ra and Rb of the present embodiment each include W element and B element. However, in the present embodiment, the B concentration in the region Ra is higher than the B concentration in the region Rb. In the present embodiment, B element is introduced into the electrode material layer 6b from the slit ST as described later, and accordingly, the B concentration in the region Ra near the slit ST becomes high and the B concentration in the region Rb far from the slit ST becomes low. The value of the B concentration in the region Rb is an example of a first value, and the value of the B concentration in the region Ra is an example of a second value.

The region Ra of the present embodiment is, for example, a tungsten boride film (WB film). The region Rb of the present embodiment may be a WB film or may be a W layer including B element as impurity element. Alternatively, the region Rb of the present embodiment may be a W layer not including B element as impurity element. In this case, the B concentration in the region Rb is zero. In a case where the electrode material layer 6b includes C element, the region Ra is, for example, a tungsten carbide film (WC film). In a case where the electrode material layer 6b includes N element, the region Ra is, for example, a tungsten nitride film (WN film).

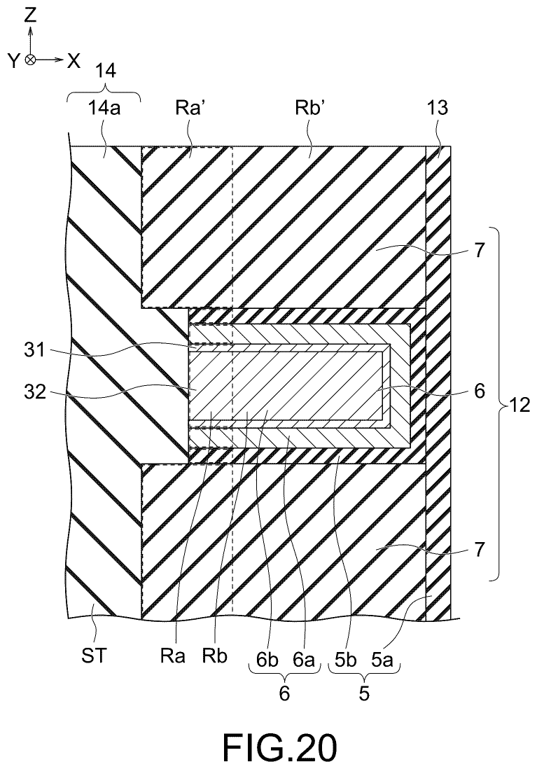

The electrode material layer 6b in each electrode layer 6 may include, in the vicinity of the barrier metal layer 6a, a layer (seed layer) that serves as the nucleus for forming the electrode material layer 6b. In this case, the seed layer may include B element before B element is introduced into the electrode material layer 6b from the slit ST. In this case, the relation of “the B concentration in the region Ra is higher than the B concentration in the region Rb” in the present embodiment holds in portions other than the seed layer in the electrode material layer 6b. An example of the seed layer will be described later with reference to FIG. 20.

In the present embodiment, when B element is introduced into the electrode material layer 6b from the slit ST, B element may also be introduced into the insulators 7, the barrier metal layer 6a, the insulator 5b, and the like. Such B element will be described later with reference to FIG. 20.

In the present embodiment, undesirable impurity atoms potentially diffuse into the electrode material layer 6b from the slit ST before the plate-like portion 14 is formed in the slit ST. Such impurity atoms are, for example, hydrogen (H) atoms. In this case, cell reliability potentially degrades due to diffusion of the impurity atoms.

Thus, in the present embodiment, the B concentration in the region Ra is set to be high. According to experiments, the region Ra where the B concentration is high acts as a barrier that reduces diffusion of the impurity atoms, and the barrier effect is enhanced in a case where the region Ra is a WB film. According to the present embodiment, since the region Ra is formed, diffusion of the impurity atoms from the slit ST into the electrode material layer 6b can be reduced by the region Ra. The region Ra may be a W layer including B element as impurity element instead of a WB film as long as diffusion of the impurity atoms can be sufficiently reduced.

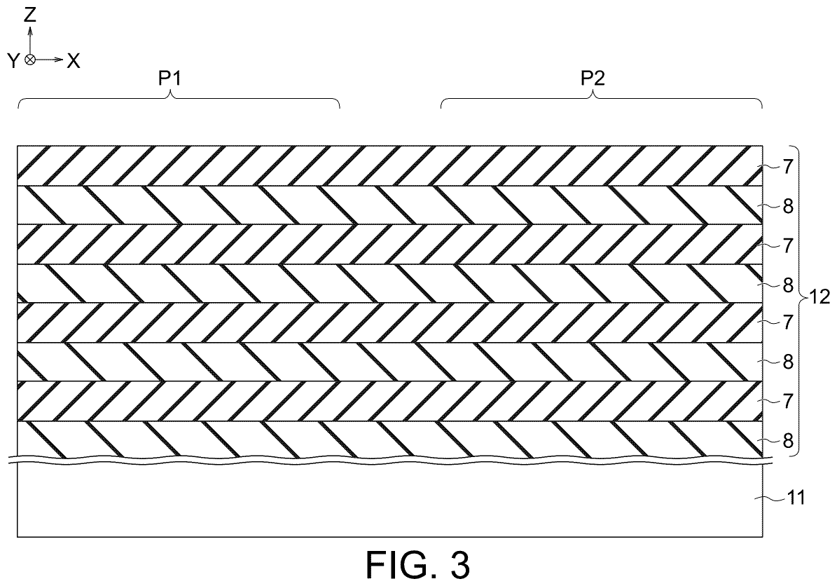

FIGS. 3 to 10 are cross-sectional views illustrating a method of manufacturing the semiconductor device of the first embodiment.

First, the stacked film 12 is formed above the substrate 11 (FIG. 3). The stacked film 12 illustrated in FIG. 3 alternately includes a plurality of sacrifice layers 8 and a plurality of insulators 7 in the Z direction. The stacked film 12 is formed by alternately stacking a plurality of sacrifice layers 8 and a plurality of the insulators 7 above the substrate 11. The sacrifice layers 8 are, for example, SiN films. Each sacrifice layer 8 is an example of a first layer. FIG. 3 illustrates the portions P1 and P2 of the stacked film 12.

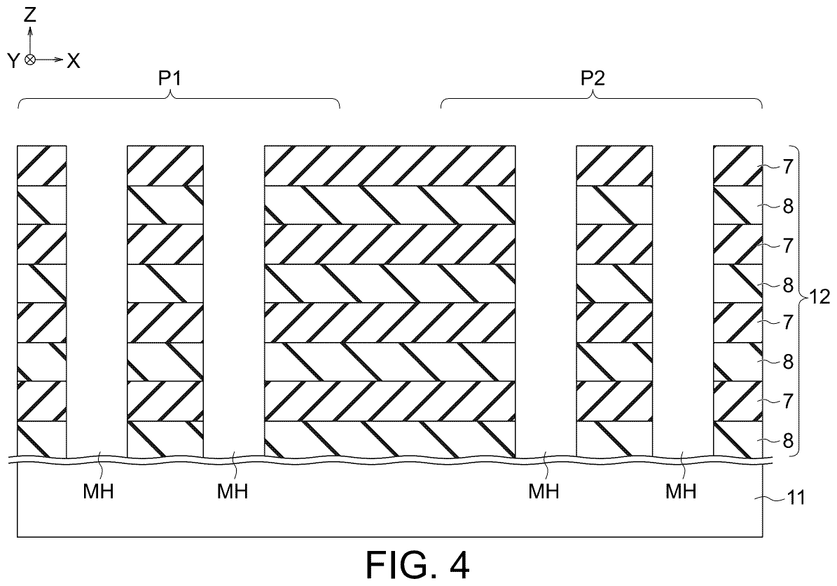

Subsequently, a plurality of memory holes MH are formed in the stacked film 12 by lithography and reactive ion etching (RIE) (FIG. 4). FIG. 4 illustrates a plurality of memory holes MH formed in the portion P1 and a plurality of memory holes MH formed in the portion P2.

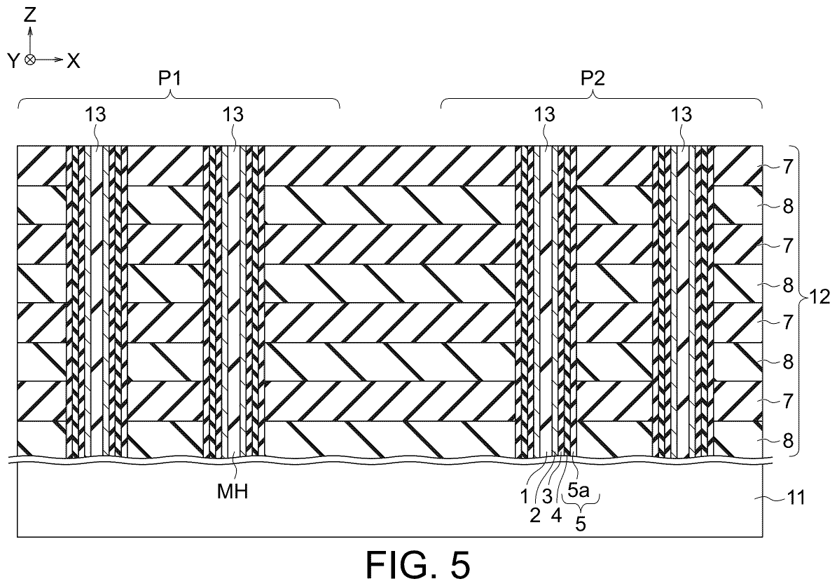

Subsequently, the core insulator 1, the channel semiconductor layer 2, the tunnel insulator 3, the charge storing layer 4, and the insulator 5a are sequentially formed in each memory hole MH (FIG. 5). As a result, the columnar portions 13 are formed in the respective memory holes MH.

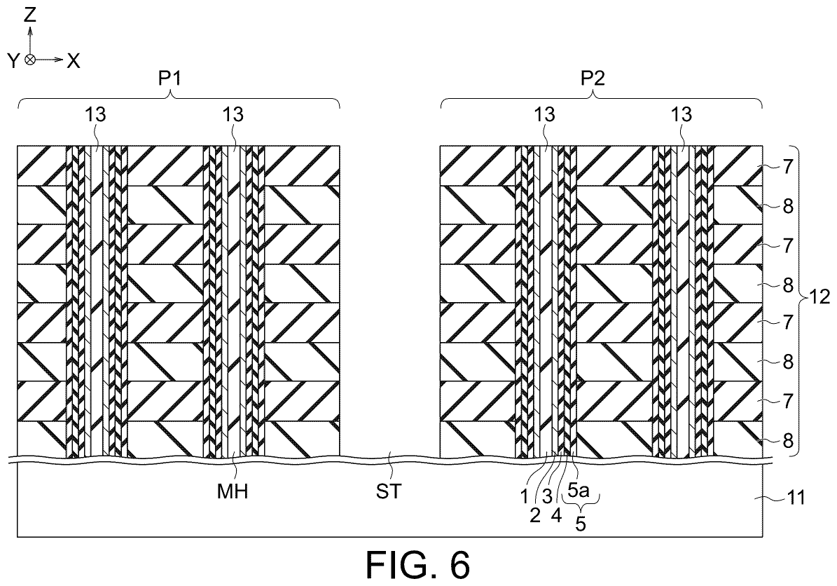

Subsequently, the slit ST is formed in the stacked film 12 by lithography and RIE (FIG. 6). The slit ST is formed between the portions P1 and P2 of the stacked film 12. As a result, the portions P1 and P2 are divided from each other by the slit ST. The slit ST is an example of a first concave portion.

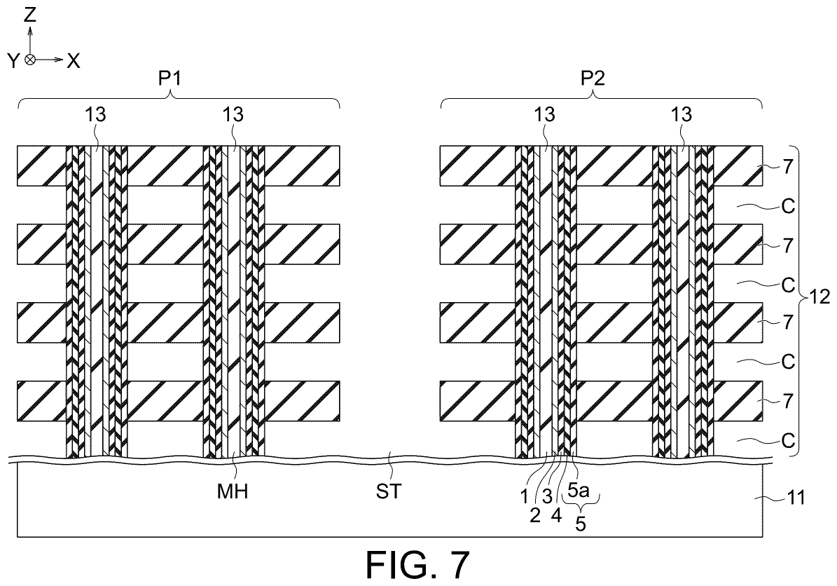

Subsequently, the sacrifice layers 8 are removed from the stacked film 12 by etching from the slit ST (FIG. 7). As a result, a plurality of cavities C are formed in the stacked film 12. Each cavity C is formed between two insulators 7 adjacent to each other in the Z direction. Each cavity C is an example of a second concave portion. The etching in FIG. 7 is, for example, wet etching. However, the etching in FIG. 7 may be dry etching.

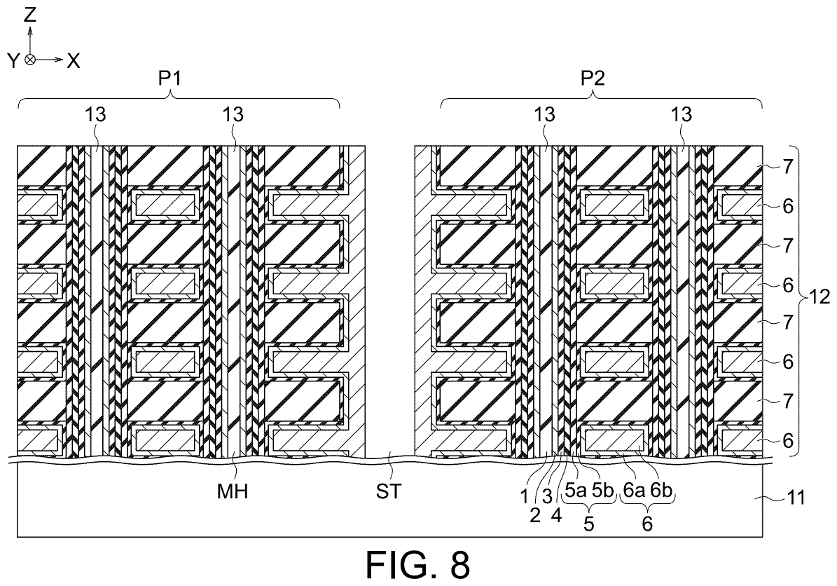

Subsequently, the insulator 5b, the barrier metal layer 6a, and the electrode material layer 6b are sequentially formed in each cavity C from the slit ST (FIG. 8). The insulator 5b, the barrier metal layer 6a, and the electrode material layer 6b are sequentially formed also on the side face of the stacked film 12 in the slit ST. In this manner, a plurality of electrode layers 6 are formed in the cavities C. The barrier metal layer 6a and the electrode material layer 6b are an example of the material of the electrode layers 6. In FIG. 8, the barrier metal layer 6a and the electrode material layer 6b are, for example, a TiN film and a W layer, respectively.

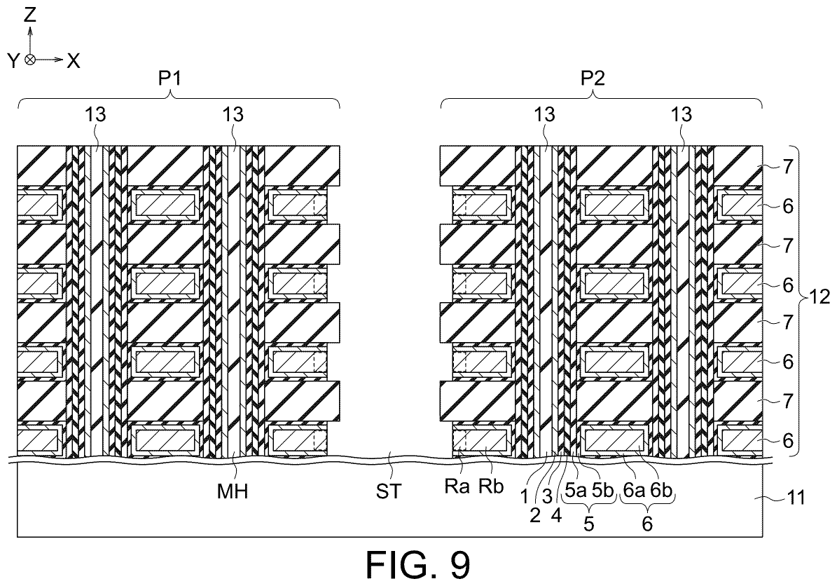

Subsequently, the electrode material layer 6b, the barrier metal layer 6a, and the insulator 5b are removed from the slit ST by lithography and RIE (FIG. 9). As a result, the electrode layers 6 are divided from each other. In this manner, the sacrifice layers 8 are replaced with the above-described electrode layers 6. In FIG. 9, portions of the electrode material layer 6b, the barrier metal layer 6a, and the insulator 5b in each concave portion C are removed.

In the process illustrated in FIG. 9, the region Ra having a high B concentration and the region Rb having a low B concentration are formed in the electrode material layer 6b of each electrode layer 6. The regions Ra and Rb are formed by, for example, introducing B element into the electrode material layer 6b of each electrode layer 6 from the slit ST. Accordingly, the B concentration in the region Ra near the slit ST becomes high, and the B concentration in the region Rb far from the slit ST becomes low. Each of the regions Ra and Rb is, for example, a WB film, or a W layer including B element as impurity element. In FIG. 9, the regions Ra and Rb are formed in the portions P1 and P2.

The regions Ra and Rb may be formed after or before the above-described electrode layers 6 are divided from each other. Details thereof will be described later.

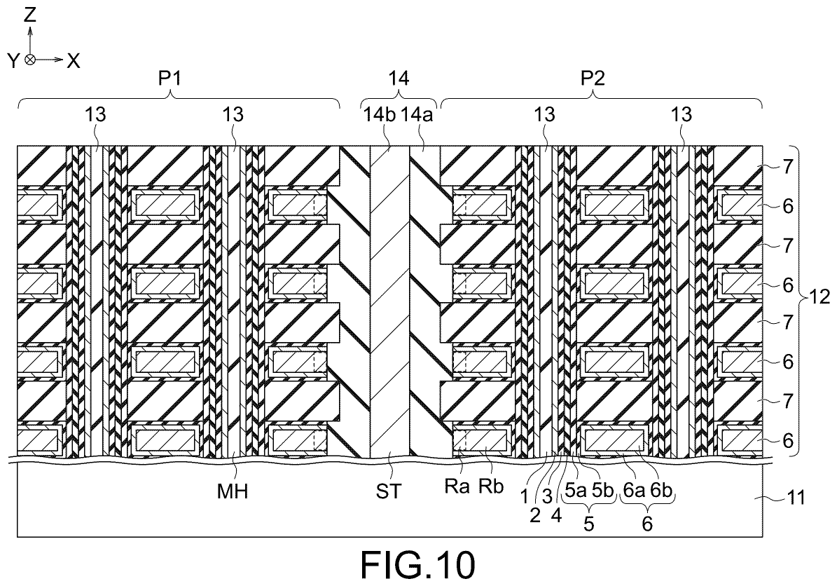

Subsequently, the insulator 14a and the interconnect layer 14b are sequentially formed in the slit ST (FIG. 10). As a result, the plate-like portion 14 is formed in the slit ST.

In this manner, the semiconductor device illustrated in FIG. 2 is manufactured.

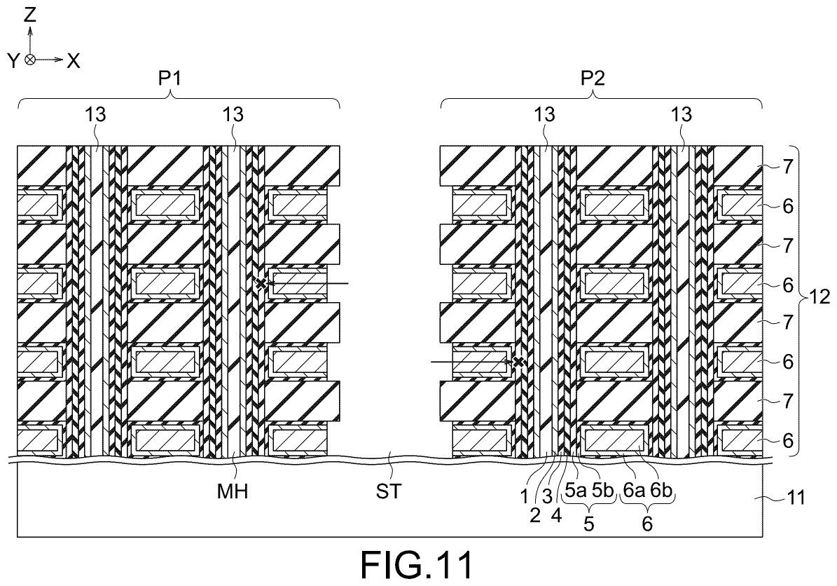

FIG. 11 is a cross-sectional view illustrating a method of manufacturing a semiconductor device of a comparative example of the first embodiment.

The cross-sectional view of FIG. 11 corresponds to the cross-sectional view of FIG. 9. However, each electrode layer 6 illustrated in FIG. 9 does not include the regions Ra and Rb in the electrode material layer 6b.

In the present comparative example, undesirable impurity atoms potentially diffuse into the electrode material layer 6b from the slit ST before the plate-like portion 14 is formed in the slit ST. Such impurity atoms are, for example, H atoms. In this case, cell reliability potentially degrades due to diffusion of the impurity atoms.

FIG. 11 schematically illustrates a situation where H atoms enter the stacked film 12 from the slit ST. The H atoms enter the stacked film 12, for example, in the form of H radicals. The H atoms are generated, for example, from process gasses or impurities when the insulator 14a (SiO₂ film) is formed in the slit ST. Impurity atoms other than the H atoms are, for example, O atoms (O radicals).

Thus, in the present embodiment, the regions Ra and Rb are formed in the electrode material layer 6b of each electrode layer 6, and the B concentration in the region Ra is set to be high. This makes it possible to reduce impurity atom diffusion from the slit ST into the electrode material layer 6b by the region Ra.

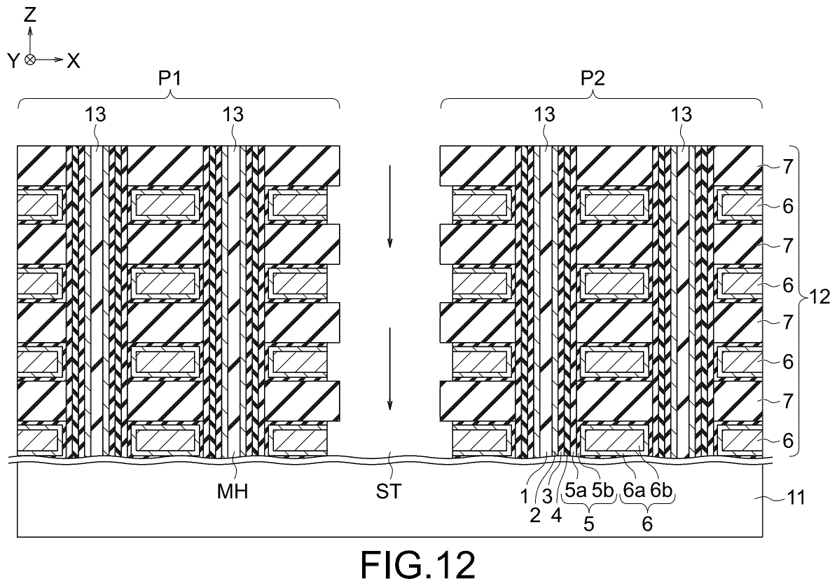

Four examples of processing of forming the regions Ra and Rb will be described below with reference to FIGS. 12 to 19.

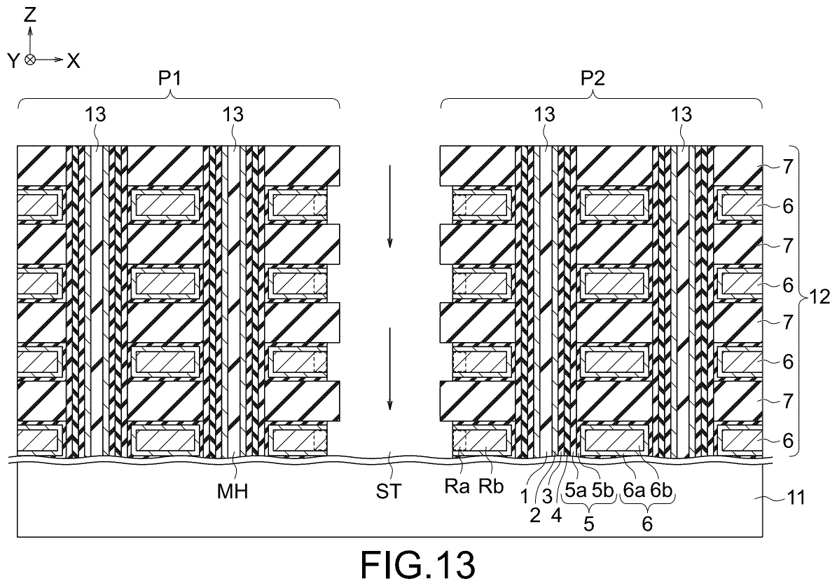

FIGS. 12 and 13 are cross-sectional views illustrating a first example of the method of manufacturing the semiconductor device of the first embodiment.

The cross-sectional view of FIG. 12 corresponds to the cross-sectional view of FIG. 9. However, FIG. 12 illustrates a state after the above-described electrode layers 6 are divided from each other and before the regions Ra and Rb are formed in the electrode material layer 6b of each electrode layer 6.

In the first example, a process gas including B element is supplied into the slit ST (FIG. 12). This process gas is, for example, B₂H₆ gas. As a result, B element derived from the B₂H₆ gas primarily enters the electrode material layer 6b in the vicinity of the slit ST. Accordingly, the regions Ra and Rb are formed in the electrode material layer 6b (FIG. 13). Thereafter, the process illustrated in FIG. 10 is performed.

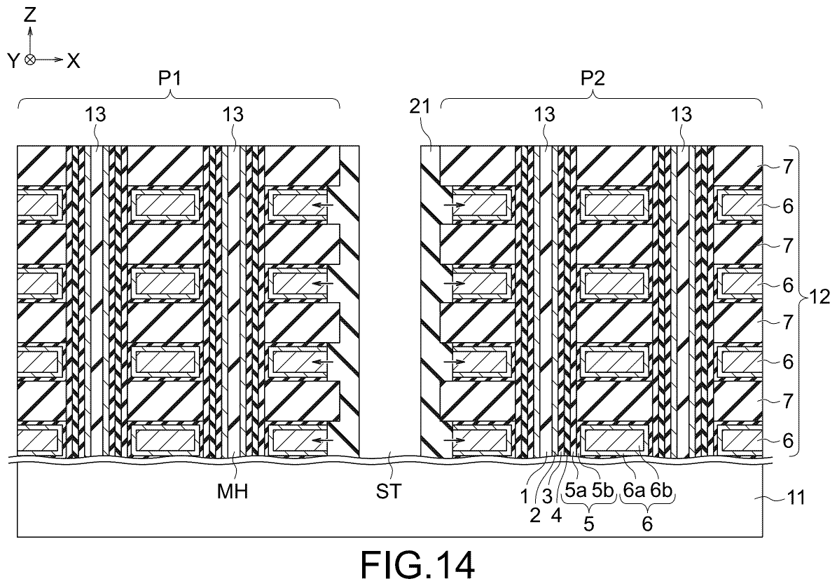

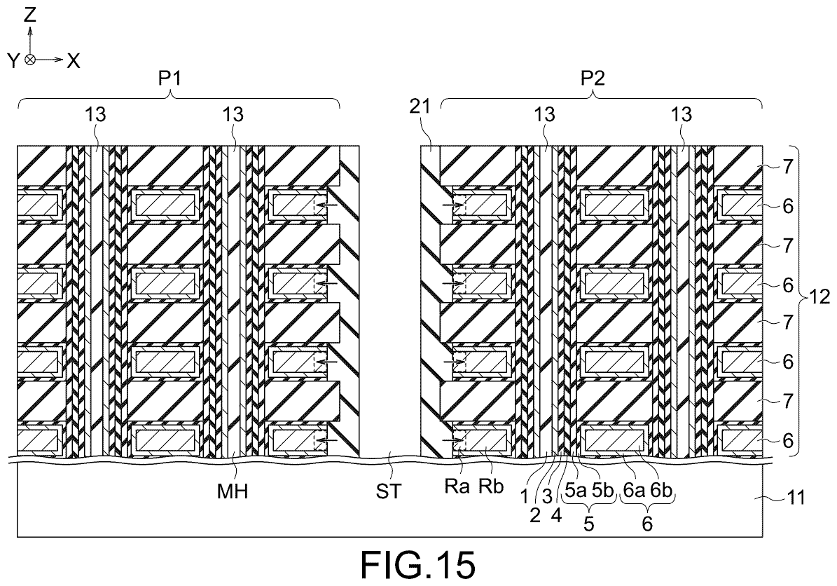

FIGS. 14 and 15 are cross-sectional views illustrating a second example of the method of manufacturing the semiconductor device of the first embodiment.

The cross-sectional view of FIG. 14 corresponds to the cross-sectional view of FIG. 9. However, FIG. 14 illustrates a state after the above-described electrode layers 6 are divided from each other and before the regions Ra and Rb are formed in the electrode material layer 6b of each electrode layer 6.

In the second example, a sacrifice layer 21 including B element is formed on the side face of the stacked film 12 in the slit ST (FIG. 14). As a result, the side face of the electrode material layer 6b is covered by the sacrifice layer 21. The sacrifice layer 21 is, for example, a borosilicate glass (BSG) layer. The sacrifice layer 21 is an example of a second layer. Subsequently, the B element included in the sacrifice layer 21 is diffused from the sacrifice layer 21 into the stacked film 12. Accordingly, the regions Ra and Rb are formed in the electrode material layer 6b (FIG. 15). The B element diffusion is caused by, for example, annealing of the sacrifice layer 21. Thereafter, the sacrifice layer 21 is removed, and then the process illustrated in FIG. 10 is performed.

The first example makes it possible to form the regions Ra and Rb through simple processing of supplying B₂H₆ gas, for example. The second example makes it possible to form the regions Ra and Rb even in a case where such gas supply is impossible, for example.

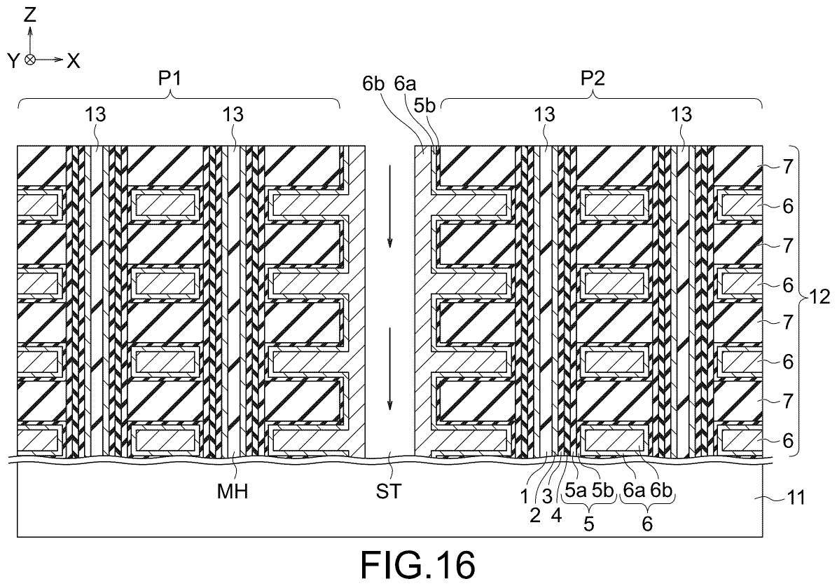

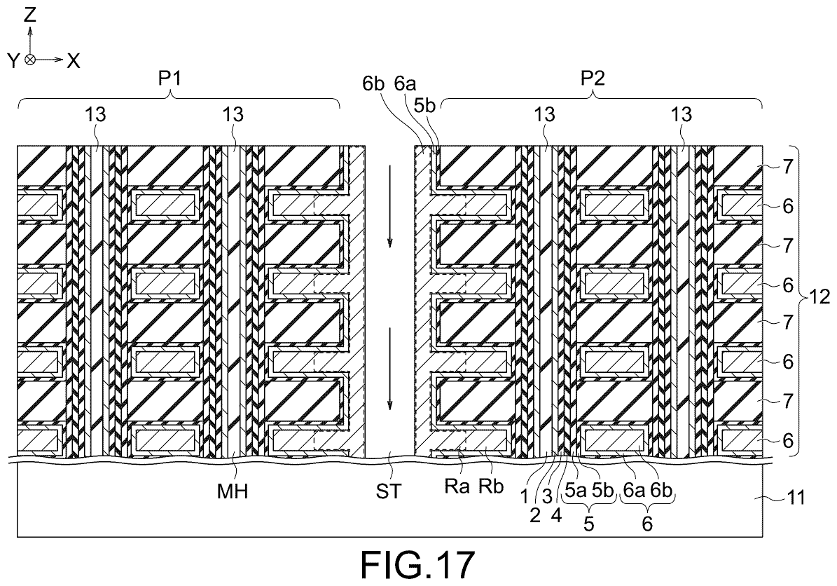

FIGS. 16 and 17 are cross-sectional views illustrating a third example of the method of manufacturing the semiconductor device of the first embodiment.

The cross-sectional view of FIG. 16 corresponds to the cross-sectional view of FIG. 8. Accordingly, FIG. 16 illustrates a state before the above-described electrode layers 6 are divided from each other and before the regions Ra and Rb are formed in the electrode material layer 6b of each electrode layer 6.

In the third example, a process gas including B element is supplied into the slit ST (FIG. 16). This process gas is, for example, B₂H₆ gas. As a result, B element derived from the B₂H₆ gas primarily enters the slit ST and the electrode material layer 6b in the vicinity of the slit ST. Accordingly, the regions Ra and Rb are formed in the electrode material layer 6b (FIG. 17). Thereafter, the above-described electrode layers 6 are divided from each other (FIG. 9), and then the process illustrated in FIG. 10 is performed.

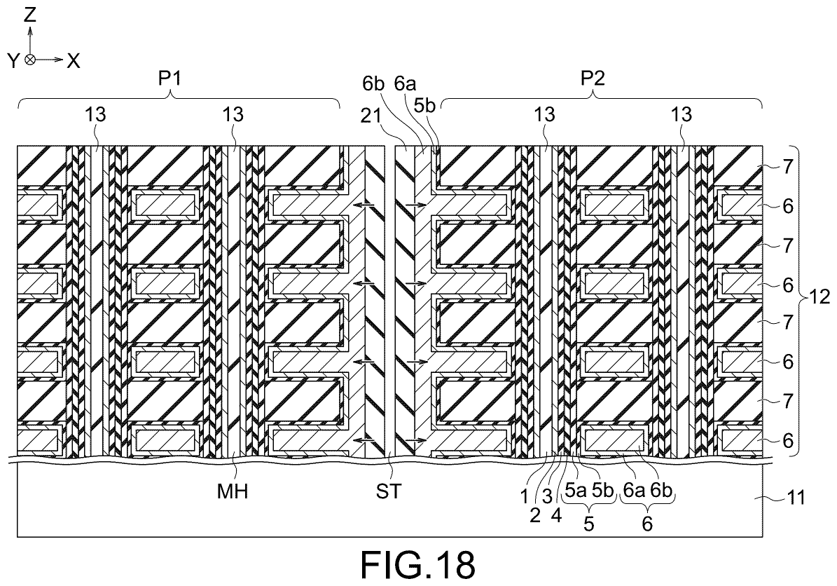

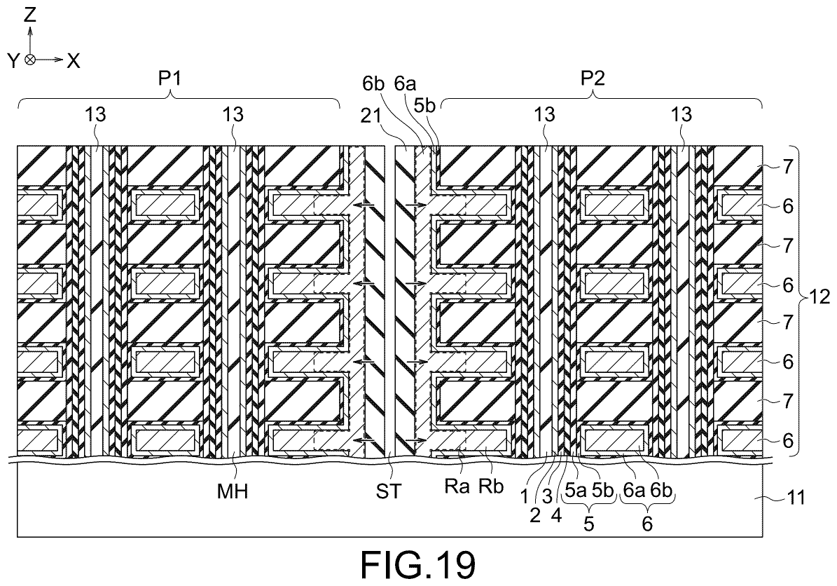

FIGS. 18 and 19 are cross-sectional views illustrating a fourth example of the method of manufacturing the semiconductor device of the first embodiment.

The cross-sectional view of FIG. 18 corresponds to the cross-sectional view of FIG. 8. Accordingly, FIG. 18 illustrates a state before the above-described electrode layers 6 are divided from each other and before the regions Ra and Rb are formed in the electrode material layer 6b of each electrode layer 6.

In the fourth example, the sacrifice layer 21 including B element is formed on the side face of the electrode material layer 6b in the slit ST (FIG. 18). As a result, the side face of the electrode material layer 6b is covered by the sacrifice layer 21. Similarly to the sacrifice layer 21 of the second example, the sacrifice layer 21 of the fourth example is, for example, a BSG layer. Subsequently, the B element included in the sacrifice layer 21 is diffused from the sacrifice layer 21 into the electrode material layer 6b. Accordingly, the regions Ra and Rb are formed in the electrode material layer 6b (FIG. 19). The B element diffusion is caused by, for example, annealing of the sacrifice layer 21. Thereafter, the sacrifice layer 21 is removed and the above-described electrode layers 6 are divided from each other (FIG. 9), and then the process illustrated in FIG. 10 is performed.

The third example makes it possible to form the regions Ra and Rb through simple processing of supplying B₂H₆ gas, for example. The fourth example makes it possible to form the regions Ra and Rb even in a case where such gas supply is impossible, for example.

In the third or fourth example, the regions Ra and Rb are formed in the process illustrated in FIG. 17 or 19 so that the regions Ra remain after the electrode layers 6 are divided. Accordingly, in FIGS. 17 and 19, the regions Ra are formed not only in the electrode material layers 6b positioned in the slit ST but also in the electrode material layers 6b positioned in the cavities C.

FIG. 20 is an enlarged cross-sectional view illustrating the structure of the semiconductor device of the first embodiment.

In FIG. 20, the electrode material layer 6b, the barrier metal layer 6a, the insulator 5a, and the insulators 7 include a region Ra′ and a region Rb′. The region Ra′ is positioned near the plate-like portion 14, and the region Rb′ is positioned far from the plate-like portion 14. The region Ra′ in the electrode material layer 6b corresponds to the above-described region Ra, and the region Rb′ in the electrode material layer 6b corresponds to the above-described region Rb. The region Ra′ is an example of a third region, and the region Rb′ is an example of a fourth region.

In the present embodiment, B element is introduced into the electrode material layer 6b from the slit ST, and accordingly, the B concentration in the region Ra near the slit ST becomes high, and the B concentration in the region Rb far from the slit ST becomes low. This phenomenon occurs in the regions Ra′ and Rb′ as well. Accordingly, the B concentration in the region Ra′ near the slit ST becomes high, and the B concentration in the region Rb′ far from the slit ST becomes low. For example, in each insulator 7, the B concentration in the region Ra′ becomes higher than the B concentration in the region Rb′. The B concentration in the region Rb′ is an example of a third value, and the B concentration in the region Ra′ is an example of a fourth value.

In FIG. 20, the electrode material layer 6b includes an electrode material layer 31 formed on the surface of the barrier metal layer 6a, and an electrode material layer 32 formed on the surface of the electrode material layer 31. The electrode material layer 32 is formed on the surface of the barrier metal layer 6a with the electrode material layer 31 in between and is positioned in the electrode material layer 31. The electrode material layer 31 is, for example, a seed layer that serves as the nucleus for forming the electrode material layer 6b. The electrode material layer 32 is, for example, a bulk layer formed by using the seed layer. The electrode material layer 31 is an example of a first film, and the electrode material layer 32 is an example of a second film.

The electrode material layer 31 may include B element before B element is introduced into the electrode material layer 6b from the slit ST. For example, in a case where the electrode material layer 31 is a seed layer, the electrode material layer 31 is typically formed to include B element. In this case, the relation of “the B concentration in the region Ra is higher than the B concentration in the region Rb” in the present embodiment holds in the electrode material layer 32. In other words, the B concentration in the region Ra provided in the electrode material layer 32 is higher than the B concentration in the region Rb provided in the electrode material layer 32.

The electrode material layer 32 is, for example, a W layer before B element is introduced into the electrode material layer 6b from the slit ST. However, after B element is introduced into the electrode material layer 6b from the slit ST, the electrode material layer 32 in the region Ra is, for example, a WB film and the electrode material layer 32 in the region Rb is, for example, a W layer including B element as impurity element.

As described above, the electrode material layer 6b in each electrode layer 6 of the present embodiment includes the regions Ra and Rb, and the B concentration in the region Ra is higher than the B concentration in the region Rb. The present embodiment makes it possible to achieve preferable electrode layers 6. For example, impurity atom diffusion from the slit ST into the electrode material layer 6b can be reduced by the region Ra, and accordingly, degradation of cell reliability can be reduced.

### Second Embodiment

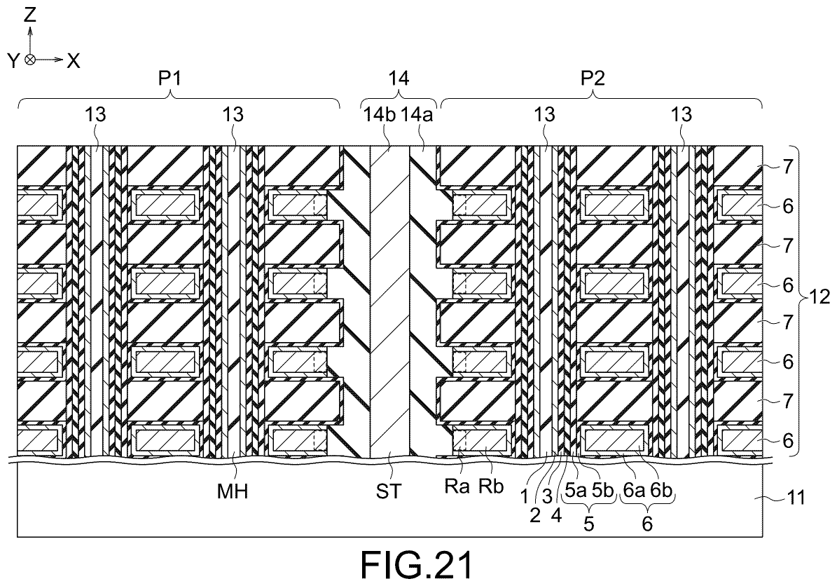

FIG. 21 is a cross-sectional view illustrating a structure of a semiconductor device of a second embodiment.

The semiconductor device of the present embodiment illustrated in FIG. 21 has a structure similar to that of the semiconductor device of the first embodiment illustrated in FIG. 2. However, the insulators 5b of the present embodiment are formed not only between each electrode layer 6 and the corresponding insulator 5a adjacent to each other and between each electrode layer 6 and the corresponding insulator 7 adjacent to each other but also between the insulator 14a and each insulator 7.

The semiconductor device of the present embodiment can be manufactured by, for example, performing the process illustrated in FIG. 9 by “isotropic etching” in place of “lithography and RIE” when the the semiconductor device is manufactured through processes illustrated in FIGS. 3 to 10. This makes it possible to remove the barrier metal layers 6a and the electrode material layers 6b from the slit ST while leaving the insulator 5b in the slit ST. The above-described isotropic etching is, for example, wet etching or chemical dry etching (CDE).

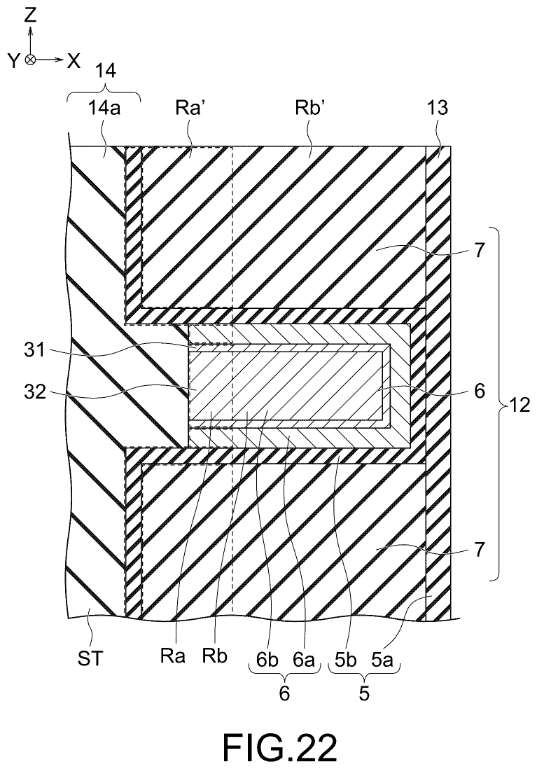

FIG. 22 is an enlarged cross-sectional view illustrating the structure of the semiconductor device of the second embodiment.

FIG. 22 of the present embodiment is a cross-sectional view corresponding to FIG. 20 of the first embodiment. In FIG. 22, the insulator 5b is formed between the insulator 14a and each insulator 7 as well. The insulator 5b formed between the insulator 14a and each insulator 7 is portion of the region Ra′.

Similarly to the first embodiment, the present embodiment makes it possible to achieve preferable electrode layers 6. Moreover, the present embodiment makes it possible to reduce impurity atom diffusion from the slit ST into the electrode material layer 6b by the insulator 5b.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a stacked film alternately including a plurality of electrode layers and a plurality of first insulators in a first direction;
a plate-like portion provided in the stacked film, having a plate-like shape that extends in the first direction and a second direction intersecting the first direction, and provided between a first portion and a second portion of the stacked film;
a first columnar portion provided in the first portion, extending in the first direction, and including a first charge storing layer and a first semiconductor layer; and
a second columnar portion provided in the second portion, extending in the first direction, and including a second charge storing layer and a second semiconductor layer,
wherein
a first electrode layer among the electrode layers includes a first region where concentration of boron, carbon or nitrogen has a first value, and a second region where concentration of boron, carbon or nitrogen has a second value higher than the first value, and
the second region is provided in a vicinity of a side face of the first electrode layer, the side face of the first electrode layer facing the plate-like portion.

2. The device of claim 1, wherein the second region includes a metal element, and boron, carbon or nitrogen.

3. The device of claim 2, wherein the second region is formed of a metal boride film, a metal carbide film or a metal nitride film.

4. The device of claim 2, wherein the metal element is a transition metal element.

5. The device of claim 2, wherein the metal element is a Group 4 element, a Group 5 element or a Group 6 element.

6. The device of claim 2, wherein the metal element is titanium (Ti), zirconium (Zr), hafnium (Hf), vanadium (V), niobium (Nb), tantalum (Ta), chromium (Cr), molybdenum (Mo) or tungsten (W).

7. The device of claim 1, wherein the second region is provided in the first electrode layer positioned in the first portion, and is provided in the first electrode layer positioned in the second portion.

8. The device of claim 1, wherein the plate-like portion includes a second insulator provided on a side face of the stacked film, and an interconnect layer provided on a side face of the second insulator.

9. The device of claim 1, wherein
the first electrode layer includes a first film and a second film provided in the first film, and
the first electrode layer includes the first region and the second region in the second film.

10. The device of claim 1, wherein
at least one of the first insulators includes a third region where concentration of boron, carbon or nitrogen has a third value, and a fourth region where concentration of boron, carbon or nitrogen has a fourth value higher than the third value, and
the fourth region is provided in a vicinity of a side face of the at least one first insulator, the side face of the at least one first insulator facing the plate-like portion.

11. A method of manufacturing a semiconductor device, comprising:
forming a stacked film alternately including a plurality of first layers and a plurality of first insulators in a first direction;
forming a first columnar portion in a first portion of the stacked film, the first columnar portion extending in the first direction and including a first charge storing layer and a first semiconductor layer;
forming a second columnar portion in a second portion of the stacked film, the second columnar portion extending in the first direction and including a second charge storing layer and a second semiconductor layer;
forming a first concave portion in the stacked film, the first concave portion having a plate-like shape that extends in the first direction and a second direction intersecting the first direction, and is positioned between the first portion and the second portion;
replacing the first layers with a plurality of electrode layers from the first concave portion; and
forming a plate-like portion in the first concave portion, the plate-like portion having a plate-like shape that extends in the first direction and the second direction,
wherein
a first electrode layer among the electrode layers is formed to include a first region where concentration of boron, carbon or nitrogen has a first value, and a second region where concentration of boron, carbon or nitrogen has a second value higher than the first value, and
the second region is formed in a vicinity of a side face of the first electrode layer, the side face of the first electrode layer facing the first concave portion.

12. The method of claim 11, wherein the second region is formed in the first electrode layer by supplying gas including boron, carbon or nitrogen into the first concave portion.

13. The method of claim 11, wherein the second region is formed by forming a second layer including boron, carbon or nitrogen on the side face of the first electrode layer, and diffusing boron, carbon or nitrogen from the second layer into the first electrode layer.

14. The method of claim 11, wherein the replacement is performed by:
removing the first layers from the stacked film to form a plurality of second concave portions in the stacked film,
forming a material of the electrode layers in the second concave portions and the first concave portion, and
removing the material from the first concave portion to divide the electrode layers from each other.

15. The method of claim 14, wherein the second region is formed after the electrode layers are divided from each other.

16. The method of claim 14, wherein the second region is formed before the electrode layers are divided from each other.

17. The method of claim 11, wherein the second region is formed to include a metal element, and boron, carbon or nitrogen.

18. The method of claim 11, wherein the second region is formed in the first electrode layer positioned in the first portion, and is formed in the first electrode layer positioned in the second portion.

19. The method of claim 11, wherein the plate-like portion is formed after the second region is formed in the first electrode layer.

20. The method of claim 11, wherein the plate-like portion is formed by sequentially forming a second insulator and an interconnect layer in the first concave portion.
